(19) United States
(12) Patent Application Publication
(10) Pub. No.: US 2026/0344425 A1
(43) Pub. Date: Oct. 29, 2026

(54) HEAT DISSIPATING METAL-CORE-ORGANIC-SUBSTRATE

(71) Applicant: INTERNATIONAL BUSINESS MACHINES CORPORATION, Armonk, NY (US)

(72) Inventors: John Knickerbocker, Monroe, NY (US); Keiji Matsumoto, Yokohama-shi (JP); Mukta Ghate Farooq, Hopewell Junction, NY (US); John W. Golz, Hopewell Junction, NY (US); Todd Edward Takken, Brewster, NY (US)

(21) Appl. No.: 19/187,081

(22) Filed: Apr. 23, 2025

(51) Int. Cl. H10W 40/25; H10W 40/22; H10W 70/685; H10W 74/15; H10W 90/00

(52) U.S. Cl. CPC H10W 40/255; H10W 40/22; H10W 70/685; H10W 74/15; H10W 90/724; H10W 90/734

(57) ABSTRACT

A package substrate includes a build-up layer. A metal core is disposed within the build-up layer and positioned near a surface of the package substrate. A plurality of vias extend through the build-up layer, where some of the vias provide thermal conduction paths to the metal core.

### BACKGROUND

The present invention generally relates to semiconductor devices and processing methods, and more particularly to a metal-core–organic-substrate having heat dissipating structure and features.

An intermediate substrate can be employed between printed circuit boards and chips in semiconductor device packaging. The intermediate substrate can include a metal core centered in a middle of the thickness of the substrate. The metal core is encapsulated in an insulating layer. The insulator includes an equal thickness above and below the metal core. The metal core offers superior mechanical strength and rigidity compared to traditional organic substrates. The metal core is centered to permit equal bending response on the top and the bottom.

However, the conventional intermediate substrate still suffers from degraded cooling performance since the core-in-the-middle substrate does not conduct heat well since the metal core is buried within the insulating layer. A need exists for improved heat dissipation in packaging substrates.

### SUMMARY

In accordance with an embodiment of the present invention, a package substrate includes a build-up layer, and an off-center metal core disposed within the build-up layer and positioned near a surface of the package substrate. A plurality of vias extend through the build-up layer, wherein at least some of the vias provide thermal conduction paths to the metal core.

In other embodiments, the metal core can include thermal conduction regions configured to direct heat from a power and ground region of a chip to a periphery of the metal core. The metal core can include open regions configured to allow signal wires to be routed to and from a chip. The open regions can include space for wiring connections to signal vias. A heat spreader thermally coupled to the metal core at a periphery of the package substrate can be included. The at least some of the vias can include portions positioned to align with hotspots on a chip. The at least some of the vias in the portions aligned with the hotspots can be configured to function as thermal vias to carry away heat from the hotspots. A second metal core can be disposed within the build-up layer and positioned near an opposite surface of the package substrate from the metal core. The metal core can include a plurality of metal blocks surrounded by dielectric material. A second metal core can be disposed within the build-up layer and positioned near a peripheral region of the package substrate.

In accordance with another embodiment of the present invention, a package substrate includes a build-up layer, and a metal core disposed within the build-up layer and positioned near a surface of the package substrate. A chip is mounted on the surface of the package substrate. Thermal conduction regions in the metal core are configured to direct heat from power areas of the chip to a periphery of the metal core. Open regions in the metal core are configured to allow signal wires to be routed to and from the chip.

In other embodiments, vias can extend from the thermal conduction regions and channeling heat to a heat spreader disposed on the package substrate. The open regions can include space for wiring connections to signal vias. Thermal vias can be positioned to align with hotspots on the chip. A second metal core can be disposed within the build-up layer and positioned near an opposite surface of the package substrate from the metal core.

In accordance with another embodiment of the present invention, a package substrate includes a build-up layer, and a metal core disposed within the build-up layer. A chip is mounted on a surface of the package substrate. The metal core includes thermal conduction regions aligned with a power and ground region of the chip and open regions surrounding the thermal conduction regions.

In other embodiments, the thermal conduction regions can provide a heat transfer path that extends from an area under the power and ground region of the chip to a periphery of the metal core. The open regions can be configured to allow signal wires to be routed to and from the chip. Transition vias in the thermal conduction regions can be included, wherein the transition vias provide thermal conduction paths from the power and ground region of the chip to the metal core. The thermal conduction regions can include portions extending radially outward from an area under the power and ground region of the chip.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view of a semiconductor device having a printed circuit board (PCB) connected to a metal core organic substrate (MCOS) or package substrate, where the package substrate includes metal cores positioned near a chip and the connected PCB to enhance heat transfer, in accordance with an embodiment of the present invention;

FIG. 2 shows a cross-sectional view of a package substrate with two metal cores disposed at the top and bottom of a build-up layer, in accordance with an embodiment of the present invention;

FIG. 3 shows a cross-sectional view of a package substrate with a single metal core positioned at the top of a build-up layer, in accordance with an embodiment of the present invention;

FIG. 4 shows a cross-sectional view of a package substrate with a metal core at the top of a build-up layer and a partial or peripheral metal core at the bottom, providing heat dissipation off the build-up layer, in accordance with an embodiment of the present invention;

FIG. 5 shows a cross-sectional view of a package substrate with a metal core at the top of a build-up layer, another metal core at the center, and a peripheral metal core at the bottom, in accordance with an embodiment of the present invention;

FIG. 6 shows a cross-sectional view of a package substrate with two metal cores at the top and bottom of a build-up layer, and a third metal core at the center, in accordance with an embodiment of the present invention;

FIG. 7 shows a top view of a package substrate with a chip mounted on it, providing a structure of a metal core that includes thermal conduction regions and open regions for signal escape, in accordance with an embodiment of the present invention;

FIG. 8 shows a cross-sectional view of the package substrate from FIG. 7, showing the chip, metal cores, build-up layers, and heat dissipation features including thermal vias and a heat spreader, in accordance with an embodiment of the present invention; and

FIG. 9 shows a cross-sectional view of a package substrate with a chip mounted thereon, showing metal cores and heat transfer paths from power and ground regions, including hotspots, to the metal core and heat spreader, in accordance with an embodiment of the present invention.

### DETAILED DESCRIPTION

In accordance with embodiments of the present invention, devices and methods are described which include a package substrate. The package substrate can include a metal core organic substrate (MCOS) having a core metal positioned to enhance heat transfer. The package substrate can further include openings at hot spots and other regions to further provide heat dissipation at high heat load regions. In an embodiment, the package substrate is positioned with a high thermal conductivity core disposed close to chips or other components, such as a printed circuit board (PCB). In an embodiment, bending stress can be asymmetrical for top versus bottom bending. In other embodiments, the package substrate includes a plurality of layers. The plurality of layers can include multiple metal cores and insulating layers. In this way, symmetrical bending performance can be restored. The symmetry can also assist in preventing warpage of the package substrate.

Cut outs or open spaces through the insulating layer can be placed to expose areas of the core to enable signal escape regions where signal wires can be routed to and from the chip. A thermal conduction region is enabled at a periphery of a die or chip (signal area) to interact with the heat dissipating features of the package substrate.

In an embodiment, a package substrate has a metal core positioned in an upper area of the package substrate to achieve higher cooling performance as the metal core is located closer to transistors or other heat generating elements. The construction of the package substrate can include fabricating a metal core and then building up insulating layers above and/or below the metal core. In some embodiments, multiple metal cores can be employed, which can be laminated using build-up layers. Chips (chiplets) or other components are bonded to the package substrate. A heat spreader or other mechanism can be mounted to further dissipate heat.

Thermal management of a back side power distribution networks (BSPDNs) and three-dimensional integrated circuits (3D-IC or 3Di) which include stacking multiple chips or wafers vertically and interconnecting them to create a single, high-performance package) is challenging. Organic-substrate heat dissipation provides improved thermal performance, which is valuable from a system perspective, e.g., where BSPDN and 3Di are employed.

In accordance with embodiments of the present invention, a package substrate includes a high thermal conductivity core, such as but not limited to a metal or metal compound, such as, e.g., CuMo, CuW, CuC, Graphite, a ceramic (e.g., AlN, GaN, SiC, BN, BeO), diamond, Si, etc. The high thermal conductivity core can include partial cuts or spaces under the chip for signal wirings. The high thermal conductivity core can include partial cuts or spaces under the chip but remains continuous in some regions for thermal conduction (thermal conduction region). These thermal conduction regions can be fabricated under hot spots. Stacked vias can be employed that connect a chip and a metal or a ceramic core in thermal conduction regions. Signal wirings in open regions can include of stacked vias, including taller vias, and through-silicon-via (TSV) type vias. The high thermal conductivity core is separated into multiple parts and at least one part can be located closer to the chip(s) (not located in the center of the substrate but offset from the center toward the chip(s)).

The partial cuts or spaces of each high thermal conductivity core can be optimized to minimize the warpage of a package substrate (e.g., an organic substrate) to e.g., maintain symmetry and adequate strength. Each high thermal conductivity core can include a thickness between about 0.1 mm to about 2 mm. A peripheral area of upper build-up can be eliminated to expose the high thermal conductivity core, and a heat spreader can be provided in direct contact with the high thermal conductivity core through a thermal interface material (TIM). The peripheral area of upper build-up can be implemented with high density thermal vias, and a heat spreader can directly contact a surface of the package substrate through thermal interface material (TIM). Each high thermal conductivity core can be connected with stacked vias or thermal vias.

In accordance with an embodiment of the present invention, a package substrate includes a build-up layer, and an off-center metal core disposed within the build-up layer and positioned near a surface of the package substrate. A plurality of vias extend through the build-up layer, wherein at least some of the vias provide thermal conduction paths through the at least some of the vias to the metal core.

In other embodiments, the metal core can include thermal conduction regions configured to direct heat from a power and ground region of a chip to a periphery of the metal core. The metal core can include open regions configured to allow signal wires to be routed to and from the chip. The open regions can include space for wiring connections to signal vias. A heat spreader thermally coupled to the metal core at a periphery of the package substrate can be included. The at least some of the vias can include portions positioned to align with hotspots on a chip. The at least some of the vias in the portions aligned with the hotspots can be configured to function as thermal vias to carry away heat from the hotspots. A second metal core can be disposed within the build-up layer and positioned near an opposite surface of the package substrate from the metal core. The metal core can include a plurality of metal blocks surrounded by dielectric material. A second metal core can be disposed within the build-up layer and positioned near a periphery of the package substrate.

In accordance with another embodiment of the present invention, a package substrate includes a build-up layer, and a metal core disposed within the build-up layer and positioned near a surface of the package substrate. A chip is mounted on the surface of the package substrate. Thermal conduction regions in the metal core are configured to direct heat from power areas of the chip to a periphery of the metal core. Open regions in the metal core are configured to allow signal wires to be routed to and from the chip.

In other embodiments, vias can extend from the thermal conduction regions and channeling heat to a heat spreader disposed on the package substrate. The open regions can include space for wiring connections to signal vias. Thermal vias can be positioned to align with hotspots on the chip. A second metal core can be disposed within the build-up layer and positioned near an opposite surface of the package substrate from the metal core.

In accordance with another embodiment of the present invention, a package substrate includes a build-up layer, and a metal core disposed within the build-up layer. A chip is mounted on a surface of the package substrate. The metal core includes thermal conduction regions aligned with a power and ground region of the chip and open regions surrounding the thermal conduction regions.

In other embodiments, the thermal conduction regions can provide a heat transfer path that extends from an area under the power and ground region of the chip to a periphery of the metal core. The open regions can be configured to allow signal wires to be routed to and from the chip. Transition vias in the thermal conduction regions can be included, wherein the transition vias provide thermal conduction paths from the power and ground region of the chip to the metal core. The thermal conduction regions can include portions extending radially outward from an area under the power and ground region of the chip.

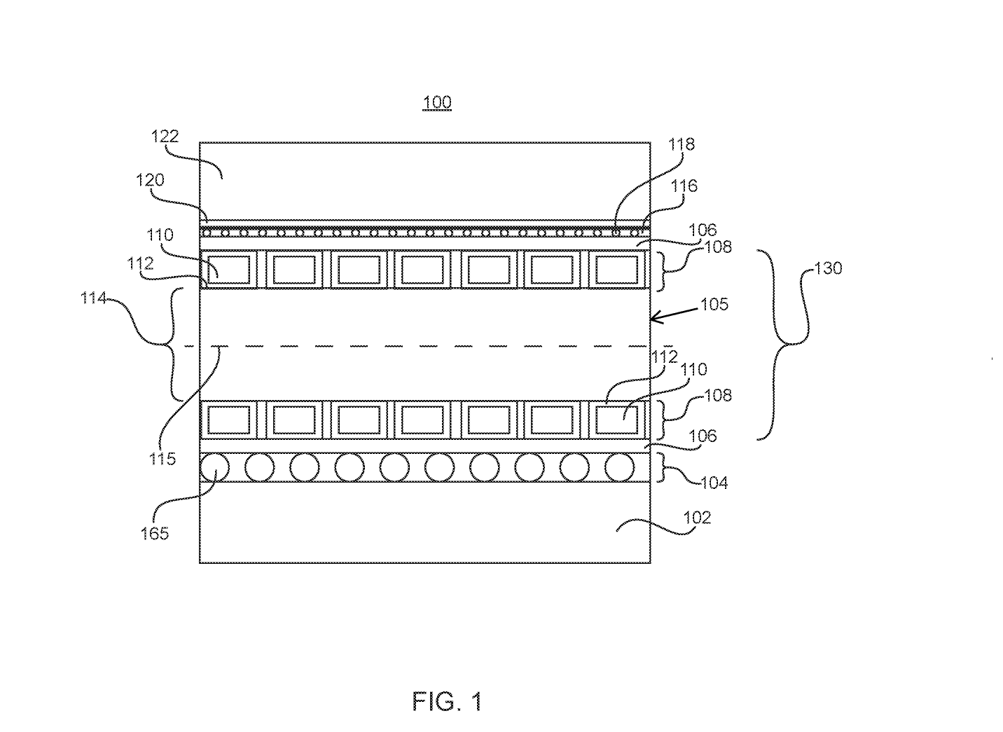

Referring now to the drawings in which, like numerals represent the same or similar elements and initially to FIG. 1, a cross-sectional view of a semiconductor device 100 is shown in accordance with embodiments of the present invention. The semiconductor device 100 includes a printed circuit board (PCB) 102. The PCB 102 can include a laminated structure of conductive and insulating layers that provides a mechanical base for holding and connecting electronic components. The PCB 102 is connected to a package substrate 130. The package substrate 130 can be a metal core organic substrate (MCOS) in accordance with embodiments of the present invention. The PCB 102 and the package substrate 130 can be connected with solder balls 165 in a ball grid array (BGA) 104. Conductive paths can run through the package substrate 130 and make electrical connection between a chip 122 and the PCB 102. It should be understood that there are many configurations that can be realized using package substrate 130. FIG. 1 shows an illustrative configuration; however, any number of chips, PCBs and connective materials can be employed in any number of configurations.

The package substrate 130 includes metal cores 108, which include a line of metal structures 110 having a dielectric layer 112 formed around the metal structures 110. The metal structures 110 are positioned near the PCB 102 on one side and near the chip 122 on the other side. The position of the metal cores 108 in close proximity the PCB 102 and the chip 122 allows form enhanced heat transfer from the PCB 102 and the chip 122.

The metal cores 108 are embedded within a build-up layer 105 of the package substrate 130. The build-up layer 105 can include thin portions 106 that are disposed between metal core 108 and the PCB 102 and between metal core 108 and the chip 122, respectively. A central portion 114 of the build-up layer 105 separates the metal cores 108. The metal cores 108 occupy regions closer to the PCB 102 and closer to the chip 122, respectively. As such, the metal cores 108 are offset from a centerline 115 making the metal cores off-center with respect to a cross-sectional thickness of the build-up layer 105.

The PCB 102 and its adjacent metal core 108 can be separated by a thin portion 106 of the build-up layer 105. Likewise, the chip 122 and its adjacent metal core 108 can be separated by a thin portion 106 of the build-up layer 105. The build-up layer 105 or layer stack-up refers to the arrangement of insulating and conductive layers that form the package substrate 130. In some embodiments, the package substrate 130 can include other components and layers in addition to metal core 108 and the build-up layer 105. Between the metal cores 108, the central portion 114 of the build-up layer 105 is disposed. The chip 122 can be connected to the package substrate 130 using solder balls 118 (e.g., C4). The solder balls 118 connect electrical circuits of the package substrate 130 with back end of the line layer (BEOL) 120. The BEOL layer 120 includes metallization structures to connect with and electrically interact with the chip 122. The solder balls 118 can be electrically insulated using an underfill material 116.

The build-up layer 105 includes thin portions 106 and central portion 114, which can include layers of conductor and insulating materials to achieve desired electrical characteristics, mechanical stability and thermal management of the package substrate 130. The conductor layers provide conductive pathways for electrical signals, while insulation layers are provided in between the conductive layers. The insulating layers can include prepreg materials, which can include semi-cured resin-impregnated material used to bind layers together during a lamination process. A fully cured laminate that forms the base of the package substrate 130 is referred to as the core. The number of layers depends on the complexity of the circuit, routing constraints, and signal integrity requirements.

The metal cores 108 are positioned within a thickness of the package substrate 130 that is offset from the centerline 115. The centerline 115 is a center of the build-up layer 105 or the package substrate 130. Since heat is likely generated at or near the chip 122 and/or other adjacent PCBs (PCB 102), the metal cores 108 are positioned closer to these structures to enhance heat dissipation. In some embodiments, only one metal core 108 can be employed. The one metal core 108 can be disposed near the chip 122, for example. In other embodiments, the metal core 108 can be disposed near another PCB (e.g., PCB 102). In the embodiments shown in FIG. 1, symmetry exists about the centerline 115. This provides symmetrical bending and mechanical characteristics. In other embodiments, the mechanical characteristics can be asymmetrical (e.g., a single off center metal core will be more rigid on the metal core side).

The metal structures 110 can include a periodic arrangement of blocks or can include a more uniform metal layer with openings or windows for conductive paths. In still other embodiments, the metal structures 110 can include complex patterns to permit optimized heat flow and dissipation.

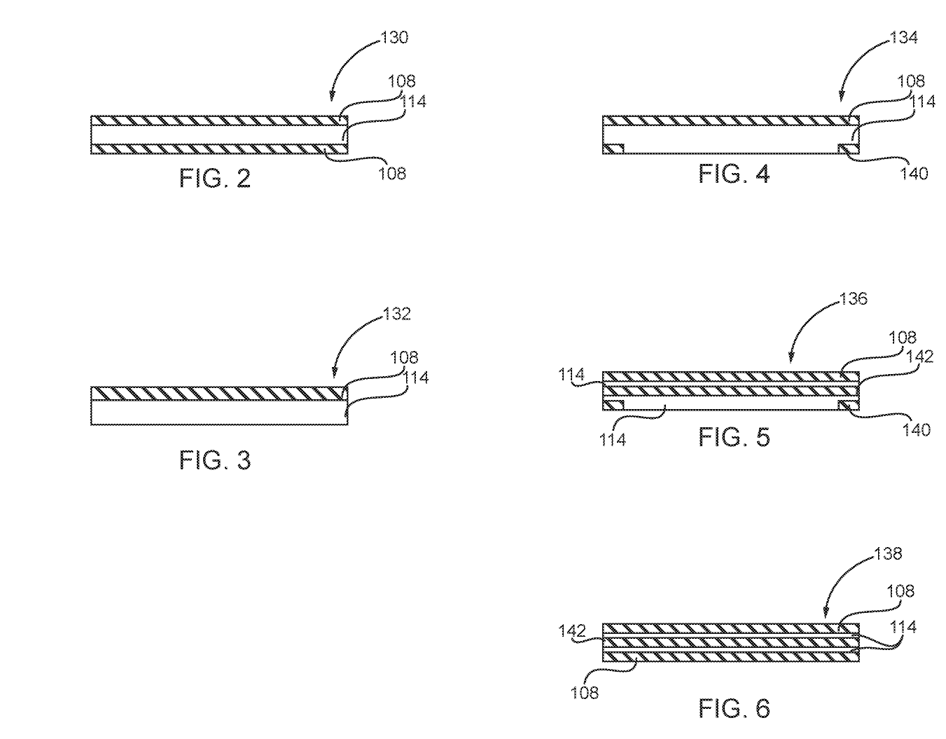

Referring to FIG. 2, a cross-section view of the package substrate 130 shows two metal layers for metal cores 108. The metal cores 108 are disposed at a top and a bottom of the central portion 114 of the build-up layer 105 (FIG. 1). The thin portions 106 have been removed for clarity. The metal cores 108 can include holes or openings (not shown) to permit electrical conductors to pass therethrough without shorting to the metal cores 108. The metal cores 108 can include blocks or portions that are distributed over a region or can include a continuous plate with openings in positions that optimize heat transfer and dissipation.

Referring to FIG. 3, a cross-section view of a package substrate 132 shows a single metal layer for metal core 108. The metal core 108 is disposed at a top of the central portion 114 of the build-up layer but could also be disposed at a bottom of the of the central portion 114. The metal core 108 can include holes or openings (not shown) to permit electrical conductors to pass therethrough without shorting to the metal cores 108. The metal core 108 can include blocks or portions that are distributed over a region or can include a continuous plate with openings in positions that optimize heat transfer and dissipation.

Referring to FIG. 4, a cross-section view of a package substrate 134 shows a metal layer for metal core 108. A partial or peripheral metal core 140 is disposed about a lower portion of the central portion 114. The peripheral metal core 140 provides heat dissipation off the of the central portion 114 of the build-up layer and can provide an interface to off-chip heat sinks or components. The metal core 108 can include holes or openings (not shown) to permit electrical conductors to pass therethrough without shorting to the metal core 108. The metal core 108 and the peripheral metal core 140 can include blocks or portions that are distributed over a region or can include a continuous plate with openings in positions that optimize heat transfer and dissipation.

Referring to FIG. 5, a cross-section view of a package substrate 136 shows the metal core 108 at a top of the central portion 114 of the build-up layer and a metal core 142 disposed at a center of the central portion 114. The peripheral metal core 140 is disposed about a lower portion of the central portion 114. The peripheral metal core 140 provides heat dissipation off of the central portion 114 of the build-up layer and can provide an interface to off-chip heat sinks or components. The metal core 108 and the metal core 142 can include holes or openings (not shown) to permit electrical conductors to pass therethrough without shorting to the metal core 108 or the metal core 142. The metal core 108, the metal core 142 and the peripheral metal core 140 can include blocks or portions that are distributed over a region or can include a continuous plate with openings in positions that optimize heat transfer and dissipation.

Referring to FIG. 6, a cross-section view of a package substrate 138 shows the two metal cores 108 at a top and bottom of the central portion 114 of the build-up layer and a metal core 142 disposed at a center of the central portion 114. The metal cores 108 and the metal core 142 can include holes or openings (not shown) to permit electrical conductors to pass therethrough without shorting to the metal cores 108 or the metal core 142. The metal cores 108 and the metal core 142 can include blocks or portions that are distributed over a region or can include a continuous plate with openings in positions that optimize heat transfer and dissipation.

It should be understood that any number of metal cores or partial metal cores can be employed in a package. In accordance with embodiments of the present invention, the package substrate can employ metal cores at strategic positions and custom shapes to guide heat flow and heat dissipation that favors temperature reduction for operating parameters of the chips or other electrical or electronic components.

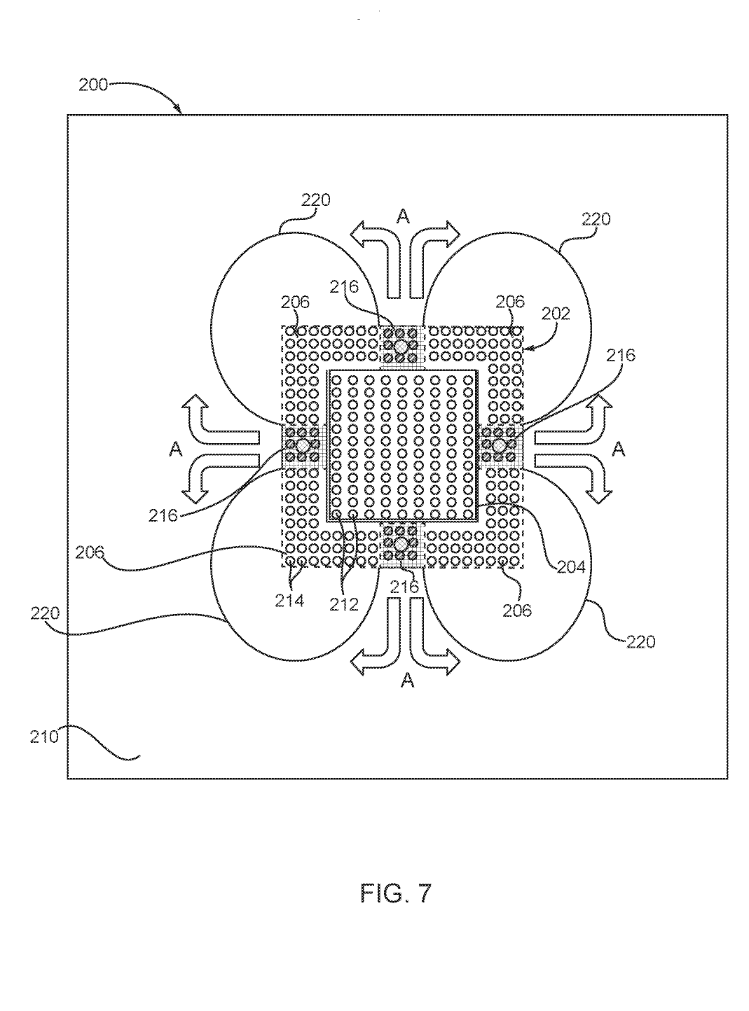

Referring to FIG. 7, a top view shows a package substrate 200 having a chip 202 mounted thereon. A metal core 210 is depicted without a build-up layer thereon to demonstrate a structure of the metal core 210. The chip 202 includes a power and ground region 204 and signal regions 206 surrounding the power and ground region 204. The power and ground region 204 is a region that can include both power conductors and ground conductors in respective areas. The power and ground region 204 includes transition vias 212 and the signal regions 206 include signal vias 214. The power and ground region 204 generates a significant amount of heat. The transition vias 212 carry heat away from the power and ground region 204 and couple the heat to the metal core 210. The transition vias 212 can also carry signals for electrical circuitry (e.g., power or group connections). While the signal vias 214 can also carry heat away from the from the chip 202, the signal vias 214 carry signals to and from the chip 202. To direct this heat away from the power and ground region 204, thermal conduction regions 216 are portions of the metal core 210 tailored to direct energy from the power and ground region 204 to a periphery of the metal core 210. The thermal conduction region 216 can include transition vias 212 to couple heat from the chip 202 to the metal core 210.

Arrows “A” show a general path of heat transfer extending radially outward from the power and ground region 204 to dissipate heat. The metal core 210 also includes open regions 220. Open regions 220 can include air gaps or dielectric material. The open regions 220 provide space for wiring connections to signal vias 214 to permit escape signals from the chip 202 (escape wiring).

The open spaces or cut outs in the metal core can serve multiple purposes in terms of heat management and signal routing. In some aspects, these open regions 220 may be strategically positioned to create thermal channels that guide heat flow in desired directions. For example, the open regions 220 may be arranged in patterns that direct heat towards the periphery of the metal core, where it can be more efficiently dissipated.

In some cases, the size and distribution of the open regions 220 can be optimized to balance thermal performance with signal routing needs. Larger open regions 220 may permit more signal traces to pass through, while smaller, more distributed openings may provide better overall thermal conductivity across the metal core 210.

The open regions 220 can also be filled with thermally conductive dielectric materials in some implementations. This approach can maintain some level of thermal conductivity while providing electrical isolation for signal traces passing through the openings.

In terms of signal escape, the open regions 220 can be mapped to accommodate various types of vias and interconnects. For example, the openings may be sized and shaped to allow for the placement of through-silicon-vias (TSVs), stacked vias, or other vertical interconnect structures. This can enable high-density signal routing from the chip 202 to other layers of the package substrate 200 while maintaining the thermal benefits of the metal core 210.

In some embodiments, a pattern of open regions 220 can be customized based on the specific thermal and signal routing requirements of the chip 202. Areas of the chip 202 with higher power density or more critical signal paths may correspond to regions of the metal core 210 with a different arrangement of openings compared to less demanding areas.

The open regions 220 can also be used to create isolated thermal zones within the metal core 210. By strategically placing openings, heat flow can be concentrated in certain areas while minimizing thermal coupling to sensitive components or regions that need lower temperatures.

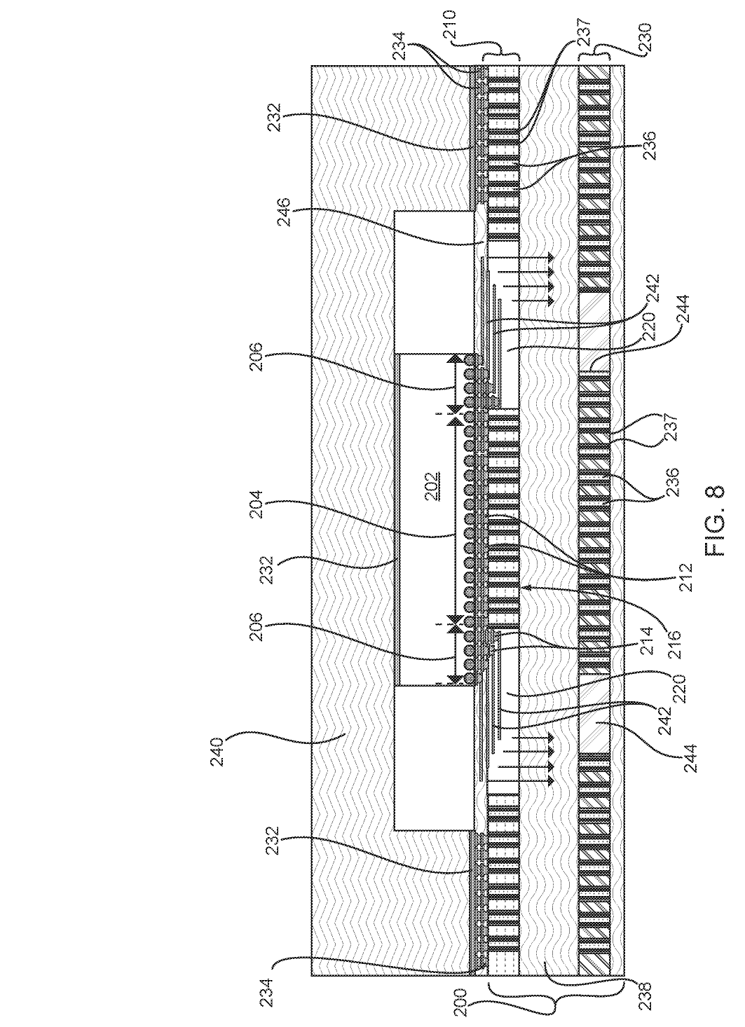

Referring to FIG. 8, a cross-sectional view of the package substrate 200 with the chip 202 mounted thereon is shown. The metal core 210 is provided on an upper portion of a build-up layer 238. Another metal core 230 is disposed at a bottom portion of the build-up layer 238. Both the metal core 210 and the metal core 230 include blocks 236 which can be surrounded by dielectric materials 237. Blocks 236 can include metals, alloys, ceramics, or other suitable conductive material(s). The metal core 230 includes windows 244 that provide openings for electrical paths.

The chip 202 includes the power and ground region 204 and signal regions 206 surrounding the power and ground region 204. The power and ground region 204 includes transition vias 212 and the signal regions 206 include signal vias 214. Other wiring features and thermal vias 234 can be employed outside a chip area.

The power and ground region 204 generates a significant amount of heat. To direct this heat away from the power and ground region 204, thermal conduction regions 216 include portions of the metal core 210 tailored to direct energy from the power and ground region 204 to a periphery of the metal core 210. The thermal conduction regions 216 can also include transition vias 212. At the periphery of the metal core 210, the thermal vias 234 can provide a heat conduction path, e.g., from the metal core 210 through a thermal interface material (TIM) 232 to a heat spreader 240, which can efficiently dissipate heat. The TIM 232 can include, e.g., a thermal paste or adhesive, to improve thermal coupling between components, e.g., between the thermal vias 234 and the heat spreader 240.

The heat spreader 240 can also be connected to a top side of the chip 202 to dissipate heat from the chip 202 from the top side of the chip 202. The heat spreader 240 includes a high thermal conductivity material, such as, e.g., copper, aluminum, diamond, etc. to transfer heat away from a heat-generating source (e.g., the chip 202) and spread it over a larger area for more efficient dissipation. The heat spreader 240 can include an integrated heat spreader (IHS).

The metal core 210 also includes open regions 220 for signal escape. Open regions 220 can include air gaps or dielectric material. The open regions 220 provide space for wiring connections 242 to signal vias 214 to permit escape signals from the chip 202. A layer 246 can be provided over the metal core 210. The layer 246 can be a dielectric layer, a build-up layer to support the formation of vias.

The thermal vias 234, the transition vias 212, and the signal vias 214 can include stacked vias, skip vias, through-silicon-vias (TSV) or any other type of vias. The thermal vias 234 provide a heat conduction path while the transition vias 212 and the signal vias 214 provide electrical and heat conduction paths. It should be understood that the vias can be employed to perform one or both of these functions as needed.

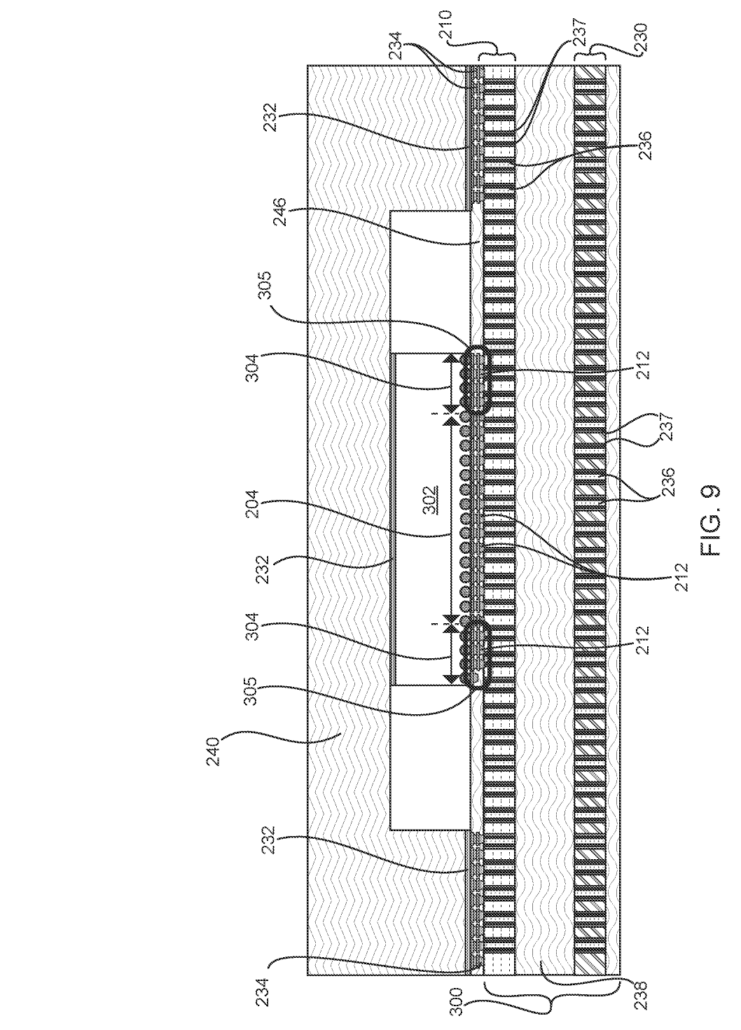

Referring to FIG. 9, a cross-sectional view of a package substrate 300 with a chip 302 mounted thereon is shown. The metal core 210 is provided on an upper portion of a build-up layer 238. Another metal core 230 is disposed at a bottom portion of the build-up layer 238. Both the metal core 210 and the metal core 230 include blocks 236, which can be surrounded by dielectric materials 237. The blocks 236 can include any suitable conductive material. The chip 302 includes the power and ground region 204 and in this example, includes regions 304, which also provide power and ground regions. The power and ground region 204 and regions 304 include transition vias 212. Other wiring features and thermal vias 234 can be employed outside the chip area.

The power and ground region 204 and regions 304 generate a significant amount of heat. To direct this heat away, thermal conduction through the metal core 210 near a surface of the package substrate 300 directs energy from the power and ground region 204 and regions 304 to a periphery of the metal core 210. At the periphery of the metal core 210, the thermal vias 234 can provide a heat conduction path, e.g., from the metal core 210 through the thermal interface material (TIM) 232 to a heat spreader 240, which can efficiently dissipate heat. The TIM 232 can include, e.g., a thermal paste or adhesive, to improve thermal coupling between components, e.g., between the thermal vias 234 and the heat spreader 240.

The thermal vias 234 and the transition vias 212 can include stacked vias, skip vias, through silicon vias (TSV) or any other type of vias. The thermal vias 234 provide a heat conduction path while the transition vias 212 provide electrical and heat conduction paths. It should be understood that the vias can be employed to perform one or both of these functions as needed.

FIG. 9 shows regions 305 which represent hotspots on the chip 302. Heat transfer from the hotspots can be increased by providing a metal path to the metal core 210 at or near a surface of the package substrate 300. Transition vias 212 in regions 304 can function as thermal vias to carry away unwanted heat from hotspots. Note that the hotspots can be anywhere on the chip 302 and are illustratively depicted at a periphery of the chip 302. Transition vias 212 can be aligned with the hotspots to permit optimal heat transfer.

The heat dissipation paths may initially flow from the chip 302 through the transition vias 212 and into the metal core 210. The metal core 210, being positioned near the surface of the package substrate 300, may provide an efficient lateral heat spreading mechanism. This lateral heat spreading can help distribute the thermal load more evenly across the device.

From the metal core 210, heat may then be conducted to the periphery of the package substrate 300 where thermal vias 234 are located. These thermal vias 234 may provide vertical heat conduction paths, allowing heat to travel towards the heat spreader 240. The thermal interface material (TIM) 232 may enhance the thermal coupling between the thermal vias 234 and the heat spreader 240, to reduce thermal resistance at this interface.

In some implementations, the heat spreader 240 may serve as the final stage in the heat dissipation path, spreading the heat over a larger surface area for more efficient transfer to the ambient environment. The heat spreader 240 may also be in direct contact with the top side of the chip 302, providing an additional heat dissipation path directly from the chip surface.

The metal core 230 at the bottom of the build-up layer 238 may provide additional thermal management capabilities. In some embodiments, this lower metal core 230 may act as a secondary heat spreading layer, helping to manage heat that flows downward through the structure.

The overall heat dissipation strategy may involve a combination of conductive and spreading techniques, utilizing the high thermal conductivity of metal cores, specialized thermal vias, and heat spreading components. This multi-path approach to heat dissipation may allow for more effective thermal management, enabling higher performance and reliability in semiconductor devices.

In accordance with embodiments of the present invention, a package substrate, e.g., including a MCOS includes one or more high thermal conductivity core(s), such as but not limited to a metal or metal compound, such as, e.g., CuMo, CuW, CuC, Graphite, a ceramic (e.g., AlN, GaN, SiC, BN, BeO), diamond, Si, etc. In some embodiments, the package substrate can be included as a PCB.

Exemplary applications/uses to which the present invention can be applied include but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom,” “backside,” “frontside” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A package substrate, comprising:
a build-up layer;
an off-center metal core disposed within the build-up layer and positioned near a surface of the package substrate; and
a plurality of vias extending through the build-up layer, wherein at least some of the plurality of vias provide thermal conduction paths to the off-center metal core.

2. The package substrate of claim 1, wherein the off-center metal core includes thermal conduction regions configured to direct heat from a power and ground region of a chip to a periphery of the off-center metal core.

3. The package substrate of claim 1, wherein the off-center metal core includes open regions configured to allow signal wires to be routed to and from a chip.

4. The package substrate of claim 3, wherein the open regions include space for wiring connections to signal vias.

5. The package substrate of claim 1, further comprising:
a heat spreader thermally coupled to the off-center metal core at a periphery of the package substrate.

6. The package substrate of claim 1, wherein the at least some of the plurality of vias include portions positioned to align with hotspots on a chip.

7. The package substrate of claim 6, wherein the at least some of the plurality of vias in the portions aligned with the hotspots are configured to function as thermal vias to carry away heat from the hotspots.

8. The package substrate of claim 1, further comprising:
a second metal core disposed within the build-up layer and positioned near an opposite surface of the package substrate from the off-center metal core.

9. The package substrate of claim 1, wherein the off-center metal core includes a plurality of metal blocks surrounded by dielectric material.

10. The package substrate of claim 1, further comprising:
a second metal core disposed within the build-up layer and positioned near a peripheral portion of the package substrate.

11. The package substrate of claim 1, wherein the off-center metal core is positioned off-center with respect to a centerline through a cross-sectional thickness of the build-up layer.

12. A package substrate, comprising:
a build-up layer;
a metal core disposed within the build-up layer and positioned near a surface of the package substrate;
a chip mounted on the surface of the package substrate;
thermal conduction regions in the metal core configured to direct heat from power areas of the chip to a periphery of the metal core; and
open regions in the metal core configured to allow signal wires to be routed to and from the chip.

13. The package substrate of claim 12, further comprising:
vias extending from the thermal conduction regions and channeling heat to a heat spreader disposed on the package substrate.

14. The package substrate of claim 12, wherein the open regions include space for wiring connections to signal vias.

15. The package substrate of claim 12, further comprising thermal vias positioned to align with hotspots on the chip.

16. The package substrate of claim 12, further comprising:
a second metal core disposed within the build-up layer and positioned near an opposite surface of the package substrate from the metal core.

17. A package substrate, comprising:
a build-up layer;
a metal core disposed within the build-up layer; and
a chip mounted on a surface of the package substrate, wherein the metal core includes:
thermal conduction regions aligned with a power and ground region of the chip; and
open regions surrounding the thermal conduction regions.

18. The package substrate of claim 17, wherein the thermal conduction regions provide a heat transfer path that extends from an area under the power and ground region of the chip to a periphery of the metal core.

19. The package substrate of claim 17, wherein the open regions are configured to allow signal wires to be routed to and from the chip.

20. The package substrate of claim 17, wherein the thermal conduction regions include portions extending radially outward from an area under the power and ground region of the chip.
